(19) United States
(12) Patent Application Publication
(10) Pub. No.: US 2004/0261842 A1
(43) Pub. Date: Dec. 30, 2004

(54) Dye-sensitized solar cells including liquid type imidazolium electrolyte

(76) Inventors: Mangu Kang, Daejon (KR); Nam-Gyu Park, Daejon (KR); Kwang-Sun Ryu, Daejon (KR); Soon-Ho Chang, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/826,961

(22) Filed: Apr. 15, 2004

(30) Foreign Application Priority Data
Jun. 25, 2003 (KR) 2003-41461

(51) Int. Cl. H01L 31/00

(52) U.S. Cl. 136/263

(57) ABSTRACT

Provided is a dye-sensitized solar cell including liquid-type imidazolium material, which is liquid at a room temperature to a high temperature, as electrolyte.. The dye-sensitized solar cell includes a semiconductor electrode; a confronting electrode; and electrolyte of 1,3-vinylalkylimidazolium iodide family being inserted between the semiconductor electrode and the confronting electrode. Since the solar cell of the present research uses 1,3-vinylalkylimidazolium iodide instead of iodine-family oxidation and reduction electrolyte including organic solvent easily volatilized at a high temperature. Thus, the solar cell can have excellent thermal stability and temperature stability as well as high energy conversion efficiency.

### FIELD OF THE INVENTION

The present invention relates to a dye-sensitized solar cell; and, more particularly, to a dye-sensitized solar cell that contains 1,3-vinylalkylimidazolium iodide, which remains liquid in room temperatures through high temperatures, as electrolyte.

### DESCRIPTION OF RELATED ART

As fossil fuel reserves run dry, methods for utilizing solar energy as electric energy are drawing more attention and efforts. The fields of solar cells present a solution for both environment preservation and the problem of energy shortage, while not generating pollutant substances. Particularly, a dye-sensitized solar cell, surfaces of which are processed with solar cells by breaking down oxide particles into a nano size with the use of photosensitive dye molecules, generates electric energy as the dye absorbs light. It has advantages that it is environmentally innocuous and the manufacturing process is simple. Further efforts are made to improve electric energy generation efficiency of the dye-sensitized solar cell.

A representative example of known conventional dye-sensitized solar cell is a solar cell developed by Gratzel et al., in Switzerland in 1991. The solar cell developed by Gratzel et al. is a photoelectrochemical solar cell formed of oxide/reduction electrolyte containing nano particle oxide semiconductor cathode, platinum anode, dye coating the nano particle oxide semiconductor cathode, and oxidation/reduction electrolyte using organic solvent. It has an advantage that it has a high energy conversion efficiency and its manufacturing cost is cheap compared to conventional solar cells using a silicon semiconductor.

However, since the conventional dye-sensitized solar cell contains electrolyte prepared by dissolving solid-type oxidation/reduction chemical species in organic solvent, it can hardly be used for a long term in an external environment where the external temperature of the solar cell is increased by solar light. Due to this problem, the conventional dye-sensitized solar cell could not be commercialized, despite its excellent energy conversion efficiency and economical mass-producibility.

Much effort has been made to solve the shortcoming of the liquid-type electrolyte containing organic solvent, including the development of a gel-type polymer electrolyte whose thermal stability is improved by adding polymer materials to the electrolyte containing organic solvent. Because of the organic solvent included in the gel-type polymer electrolyte, however, the electrolyte may be volatilized. Thus, it is hard to say that it has solved the problem of weak thermal stability. Also, if the level of gelation is increased by adding more polymer materials to prevent the electrolyte from being volatilized, the ionic conductivity of the oxidation/reduction chemical species is dropped, thus reducing the energy conversion efficiency.

### SUMMARY OF THE INVENTION

It is, therefore, an object of the present invention to provide a dye-sensitized solar cell using ionic liquid and basically free from organic solvent, which has excellent thermal stability and temperature stability and remains in the state of liquid at a room temperature or a high temperature.

In accordance with an aspect of the present invention, there is provided a dye-sensitized solar cell, including: a semiconductor electrode; a confronting electrode; and electrolyte of 1,3-vinylalkylimidazolium iodide family being inserted between the semiconductor electrode and the confronting electrode.

### BRIEF DESCRIPTION OF THE DRAWINGS

The above and other objects and features of the present invention will become apparent from the following description of the preferred embodiments given in conjunction with the accompanying drawings, in which:

FIG. 1 is a cross-sectional view illustrating a dye-sensitized solar cell in accordance with the present invention;

FIG. 2 is a graph showing a thermal stability test result of 1,3-vinylhexylimidazolium iodide in accordance with the present invention;

FIG. 3 is a graph presenting a temperature stability test result of 1,3-vinylhexylimidazolium iodide in accordance with the present invention; and

FIG. 4 is a graph showing a photoconversion efficiency test result of the dye-sensitized solar cell in accordance with the present invention.

### DETAILED DESCRIPTION OF THE INVENTION

Other objects and aspects of the invention will become apparent from the following description of the embodiments with reference to the accompanying drawings, which is set forth hereinafter.

After repeated research to achieve the aforementioned technological objects, a dye-sensitized solar cell of the present invention is developed by paying attention to the fact that akylimidazol ionic liquid remains in the state of liquid at a room temperature and a high temperature and has ionic properties and that it is non-volatile and uninflammable at a wide range of temperatures by reacting against non-metal ions. The dye-sensitized solar cell uses 1,3-vinylalkylimidazolium iodide as electrolyte.

The present invention presents a dye-sensitized solar cell that includes a semiconductor electrode, a confronting electrode, and electrolyte of 1,3-vinylalkylimidazolium iodide inserted between the semiconductor electrode and the confronting electrode. Desirably, the electrolyte includes 1 to 30 mol % iodide (I₂) of the 1,3-vinylalkylimidazolium iodide. More desirably, it has the iodide dissolved in the concentration of about 5 to 10 mol %.

With reference to the drawings, preferred embodiments of the present invention will be described, hereafter.

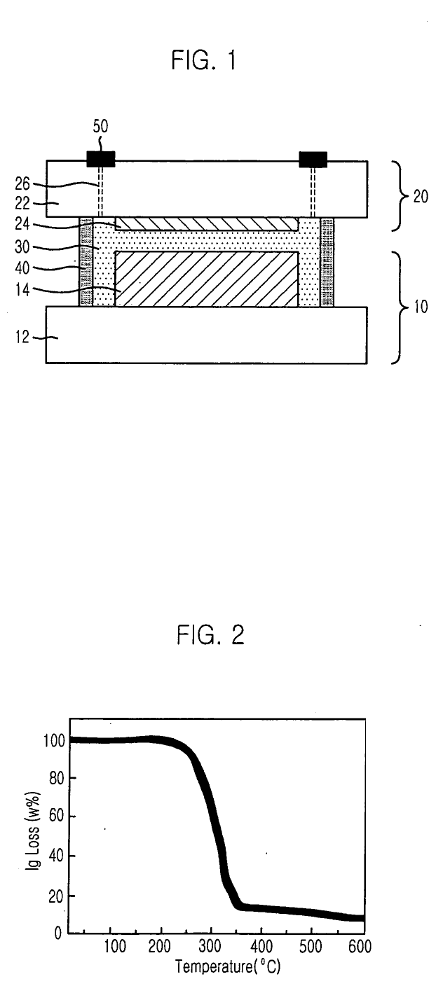

FIG. 1 is a cross-sectional view illustrating a dye-sensitized solar cell in accordance with the present invention. Referring to the drawing, the dye-sensitized solar cell includes the semiconductor electrode 10 as its cathode, the confronting electrode 20 as its anode, and the liquid-type electrolyte 30 inserted between the anode and the cathode.

The semiconductor electrode 10 is formed of a conductive transparent glass substrate 12 and a transitive metal oxide layer 14 coating the transparent glass substrate 12. On the transitive metal oxide layer 14, dye molecules are adsorbed chemically. The confronting electrode 20 that faces the semiconductor electrode 10 is formed of a conductive transparent glass substrate 22 and a platinum layer 24 coating the conductive transparent glass substrate 22.

The dye-sensitized solar cell of the present invention which has the above-described structure is manufactured as follows. First, to manufacture the semiconductor electrode 10, the conductive transparent glass substrate 12 coated with ITO or SnO₂ is prepared, and titanium dioxide is prepared to be used as the transitive metal oxide.

The titanium dioxide is prepared in the form of colloid having 15 to 30 nm titanium dioxide particles. It is prepared by preparing titanium dioxide colloid solution through hydrothermal synthesis of titanium (IV) isopropoxide and acetic acid in an autoclave in which temperature is maintained at 220° C., and evaporating solvent of the titanium dioxide colloid solution until the content of titanium dioxide within the solution becomes 10 to 15 w %.

If polyethylene glycol and polyethylene oxide are added to the colloid solution containing nano-size titanium dioxide particles to occupy around 40 w % of the total weight of titanium dioxide, viscous titanium dioxide colloid solution is obtained.

The viscous titanium dioxide colloid solution is applied to the conductive transparent glass substrate 12 already coated with ITO or SnO₂ in a thickness of 10 to 30 μm. Then the resulting material goes through annealing at a temperature of 450 to 550° C. to thereby remove polyethylene glycol and polyethylene oxide in the solution. As a result, the nano-sized oxide particles contact and fill each other. The viscous titanium dioxide colloid solution is applied to the entire surface of the conductive transparent glass substrate 12, leaving its fringes unapplied around 1 cm in four directions.

Subsequently, the conductive transparent glass substrate 12 coated with titanium dioxide is maintained in a dye solution containing ruthenium complex for 24 hours. During the process, the ruthenium complex reacts upon the titanium dioxide and adsorbs on the transitive metal oxide layer 14 to thereby form a semiconductor electrode 10.

The confronting electrode 20 is formed by preparing a conductive transparent glass substrate 22 which is the same as the conductive transparent glass substrate 12 used for fabricating the semiconductor electrode 10, coating the upper surface of the conductive transparent glass substrate 22 with platinum to thereby form a platinum layer 24. Just as the coating of the transitive metal oxide on the semiconductor electrode, the platinum coated on the confronting electrode 20 also applied to the entire surface of the conductive transparent glass substrate 22, leaving its fringes unapplied around 1 cm in four directions.

In accordance with the present invention, the liquid-type electrolyte 30 for a dye-sensitized solar cell inserted in the semiconductor electrode and the confronting electrode is a liquid mixture in which iodine is dissolved in 1,3-vinylalkylimidazolium iodide. The electrolyte can be prepared by adding N-vinylimidazol to a reaction chamber containing trichloroethylene solvent and mixing them.

During the mixing process, argon gas is injected to the trichloroethylene solvent to maintain the reaction chamber in the ambient of argon. Subsequently, hexyliodide is added to the reaction chamber slowly and the reaction chamber is maintained at 70° C. for four hours for reaction. The hexyliodide can be substituted by alkyliodide such as methyliodide, ethyliodide, propyliodide, butyliodide, heptyliodide and the like.

The added alkyliodide reacts to the N-vinylimidazol within the reaction chamber to thereby synthesize 1,3-vinylalkylimidazolium iodide. The 1,3-vinylalkylimidazolium iodide remains in the state of liquid at room temperature and polarized due to iodide ion (I⁻) contained therein. As a result, it remains separated from other non-polarized reactants within the reaction chamber due to the polarization difference. Therefore, the reaction product 1,3-vinylalkylimidazolium iodide can be separated and obtained easily.

In order to make the 1,3-vinylalkylimidazolium iodide more stable in temperature when it is used as the electrolyte for the dye-sensitized solar cell, it can exist in the form of polymer by polymerization, desirably. Finally, a predetermined amount of iodine is dissolved in the 1,3-vinylalkylimidazolium iodide solution to thereby complete the preparation of the electrolyte for the dye-sensitized solar cell. A desirable amount of iodine dissolved in the 1,3-vinylalkylimidazolium iodide solution is 1 to 30 mol % of a total weight of the 1,3-vinylalkylimidazolium iodide and, more desirably, 5 to 10 mol %.

The dissolved iodine reacts to iodide ions in the 1,3-vinylalkylimidazolium iodide solution to thereby generate I⁻ and I³⁻ ions. The reaction products react as oxidation and reduction species of the electrolyte for the dye-sensitized solar cell in the present invention.

Hereafter, a method for fabricating a solar cell by using the semiconductor electrode 10, confronting electrode 20, and 1,3-vinylhexylimidazolium iodide liquid-type electrolyte 30 will be described. First, the semiconductor electrode 10 and the confronting electrode 20 are placed to face each other. Here, the transitive metal oxide layer 14 of the semiconductor electrode 10 faces the platinum layer 24 of the confronting electrode 20.

Subsequently, the transitive metal oxide-uncoated area of the conductive transparent glass substrate 12 of the semiconductor electrode 10 is connected with the platinum-uncoated area of the conductive transparent glass substrate 22 of the confronting electrode 20 through a 30 to 50 μm polymer layer 40, such as SURLYN which is a name of product by Du Pont company.

To make the polymer layer 40 adhere strongly to the conductive transparent glass substrate 12 of the semiconductor electrode 10 and the conductive transparent glass substrate 22 of the confronting electrode 20, it is adhered with about 1 to 2 atmospheric pressure on a heating plate of about 100 to 140° C.

After the semiconductor electrode 10 and the confronting electrode 20 are connected with the polymer layer 40, a fine opening 26 is formed in the area of the confronting electrode 20 where the platinum layer 24 is not coated. Then, the liquid-type electrolyte 30 is inserted to fill the inside of a hexahedral cylinder with the 1,3-vinylhexylimidazolium iodide liquid-type electrolyte 30.

When the inside of the hexahedral cylinder is filled up with the liquid-type electrolyte 30, heat is applied to the hexahedral cylinder instantly by using a glass product 50 such as SURLYN produced by Du Pont company to close up the fine opening 26.

Followings are experimental examples for appraising the thermal stability and temperature stability of the solar cell fabricated in accordance with the present invention. The experiments are carried out with respect to a liquid-type electrolyte prepared by adding 5 mol % iodine of the total weight of 1,3-vinylhexylimidazolium iodide to 1,3-vinylhexylimidazolium iodide.

### EXPERIMENTAL EXAMPLE I

### Thermal Stability Test

Thermal stability is measured by testing the amount of volatilization. 1,3-vinylhexylimidazolium iodide was maintained in the ambient of nitrogen and the amount of volatilization is measured by raising the temperature from a room temperature to 600° C. in a temperature ascending rate of 5° C./min. FIG. 2 is a graph showing the result of the volatility test for 1,3-vinylhexylimidazolium iodide. The 1,3-vinylhexylimidazolium iodide showed little loss in weight until about 200° C. and it began volatilization at more than about 230° C.

### EXPERIMENTAL EXAMPLE II

### Temperature Stability Test

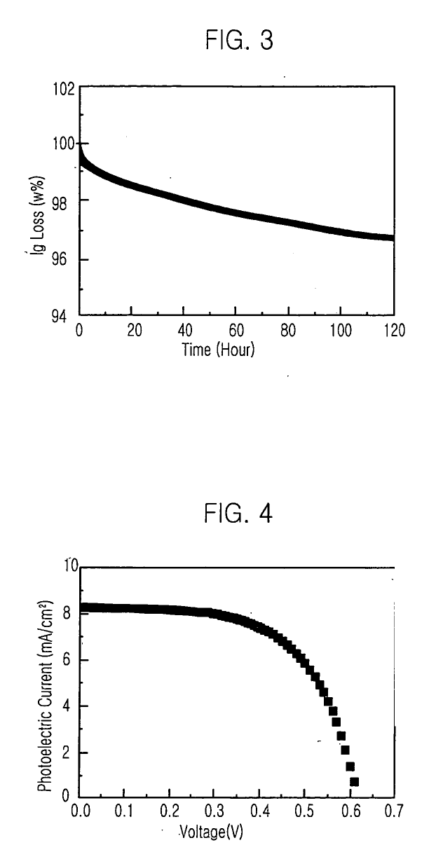

1,3-vinylhexylimidazolium iodide had been maintained at 15020 C. for five days and the change in its weight was measured to test its stability to temperature. FIG. 3 is a graph presenting the test result of 1,3-vinylhexylimidazolium iodide in accordance with the present invention. The electrolyte of the present invention showed a very slow rate of loosing its weight. For the five days, it lost about 2.5% of its weight.

From the results of FIGS. 2 and 3, it can be analogized that the electrolyte of the present invention is barely volatilized in the solar cell by a direct ray of light, when the actual usage of the electrolyte inserted between the cathode and anode of the solar cell is considered.

### EXPERIMENTAL EXAMPLE III

### Photoconversion Efficiency Test

The photoconversion efficiency of the dye-sensitized solar cell of the present invention was observed in this experiment. The solar cell used in the experiment included liquid-type electrolyte prepared by adding iodine in 1,3-vinylhexylimidazolium iodide in an amount of 5 mol % of the total weight of 1,3-vinylhexylimidazolium iodide. Light source was Xenon lamp (Oriel, 91193). Solar condition (AM 1.5) was corrected with a standard solar cell (Frunhofer Institute Solare Engeriessaysteme, Certificate No. C-ISE369, Type of material: Mono-Si+filter).

FIG. 4 is a graph showing the photoconversion efficiency test result of the dye-sensitized solar cell in accordance with the present invention. According to the result, a maximum available electric current (I_{SC}), a maximum available electric voltage (V_{OC}) and a fill factor are measured to be 8.12 mA/cm³, 0.62V and 0.6, respectively. The photoconversion efficiency for converting solar energy into electric energy is calculated as a ratio of generated electric energy (current×voltage×fill factor) to incident energy per unit area (100 mW/cm²). FIG. 4 shows that the photoconversion efficiency of the solar cell of the present invention is 3.05%.

The dye-sensitized solar cell of the present invention, which includes 1,3-vinylalkylimidazolium iodide as electrolyte can solve a volatility problem caused by using organic solvent as electrolyte in conventional technologies. Thus, it is possible to provide a long-lasting dye-sensitized solar cell with excellent stability to heat and temperature. Also, since 1,3-vinylalkylimidazolium iodide can remain in the state of liquid in a wide temperature band ranging from a room temperature to a high temperature, even when it is mixed with iodine, the ion conductivity of oxidation and reduction species is excellent. This gives high energy conversion efficiency to the solar cell.

While the present invention has been described with respect to certain preferred embodiments, it will be apparent to those skilled in the art that various changes and modifications may be made without departing from the scope of the invention as defined in the following claims.

What is claimed is:

1. A dye-sensitized solar cell, comprising:
a semiconductor electrode;
a confronting electrode; and
electrolyte of 1,3-vinylalkylimidazolium iodide family being inserted between the semiconductor electrode and the confronting electrode.

2. The dye-sensitized solar cell as recited in claim 1, wherein, in the electrolyte, 1 to 30 mol % iodine (I²) of the total weight of 1,3-vinylalkylimidazolium iodide is dissolved therein.

3. The dye-sensitized solar cell as recited in claim 1, wherein the semiconductor electrode is formed of dye molecular layer adsorbed to a conductive transparent glass substrate, a transitive metal oxide layer coating the conductive transparent glass substrate, and a transitive metal oxide layer.

4. The dye-sensitized solar cell as recited in claim 3, wherein the transitive metal oxide layer is nano-sized titanium dioxide and the dye molecular layer is ruthenium complex.
